(19) United States
(12) Patent Application Publication
(10) Pub. No.: US 2025/0250462 A1
(43) Pub. Date: Aug. 7, 2025

(54) SILICON-BEARING ENCAPSULATION FILM COMPOSITION INCLUDING SILAZANE COMPOUND AND METHOD FOR MANUFACTURING SILICON-BEARING ENCAPSULATION FILM USING SAME

(71) Applicant: DNF CO., LTD., Daejeon (KR)

(72) Inventors: Yonghee KWONE, Daejeon (KR); Youngjae IM, Daejeon (KR); Sangyong JEON, Daejeon (KR); Taeseok BYUN, Daejeon (KR); Sangchan LEE, Daejeon (KR); Sangick LEE, Daejeon (KR)

(21) Appl. No.: 18/855,145

(22) PCT Filed: Mar. 31, 2023
(86) PCT No.: PCT/KR2023/004352

§ 371 Date: Oct. 8, 2024

(30) Foreign Application Priority Data
Apr. 8, 2022 (KR) 10-2022-0043731
Mar. 29, 2023 (KR) 10-2023-0040918

(51) Int. Cl. C09D 183/16

(52) U.S. Cl. CPC C09D 183/16

(57) ABSTRACT

The present invention provides a silicon-bearing encapsulation film composition including a silazane compound and a method for manufacturing a silicon-bearing film using same, wherein the film blocks moisture and oxygen to prevent the deterioration of organic light-emitting diodes. The silicon-bearing encapsulation film composition according to the present invention can exhibit an excellent deposition rate due to the high vapor pressure thereof, and can provide a high-quality silicon-bearing encapsulation film with high purity and high durability.

### TECHNICAL FIELD

The present invention relates to a composition for a silicon-containing encapsulation film containing a silazane compound and a method for manufacturing a silicon-containing encapsulation film using the same.

### BACKGROUND ART

An organic light emitting diode (OLED) has features such as low power consumption, lightness, simplicity, a wide field of view, and a fast response, and has been already applied to smart terminals such as a smartphone and a tablet PC because it may be applied to a flexible display.

Currently, some problems still exist in the process of technological development of OLED devices, which restrict the progress of industrialization of OLED devices, and a lifespan of the device is emerging as the most important issue among them. The lifespan of the OLED device is related, on the one hand, to the performance and lifespan of the selected organic material, and on the other hand, to the packaging method of the OELD device. This is because an organic matter and a negative electrode in the OLED device react easily with moisture and oxygen. In particular, since an active metal having a thickness of several tens of nanometers is used as the negative electrode in the device, the metal reacts completely even with a trace of moisture or oxygen, and physical properties and performance of these materials are degraded or lost, and as a result, the device loses its function. Therefore, it is significantly important for the lifespan of the device to isolate each functional layer of the device from moisture and oxygen in the surrounding environment by improving the packaging effect of the device.

Traditional OLED device packaging is a method of manufacturing electrodes and respective functional layers on a substrate and then protecting the device by using a substrate having excellent chemical stability, compactness, and electrical insulation as a cover plate of the device. A glass substrate used in the method according to the related art not only may easily cause cracks or breakage of an adhesive, but also cannot satisfy requirements for a flexible effect. In addition, in the case of the glass substrate, a space occupied by the glass substrate is relatively large, which does not meet the trend of slimming the OLED device.

As a new packaging process, a thin film encapsulation (TFE) technique has been applied, and this technique is a type of gapless encapsulation method that enables physical protection of devices in an encapsulation area by forming a thin film having a dense structure. In an inorganic layer thin film encapsulation structure according to the related art, pinholes may be formed due to impurities, through which moisture and oxygen may permeate, and an organic thin film including a polymer film having excellent flexible performance has a poor ability to block moisture and oxygen. Therefore, studies on an encapsulation film having a low content of impurities and an excellent ability to block moisture and oxygen, which may solve the above problem, have been conducted.

### RELATED ART DOCUMENT

### Patent Document

(Patent Document 1) Korean Patent Laid-Open Publication No. 10-2016-0146525 A
(Patent Document 2) Korean Patent Laid-Open Publication No. 10-2015-0066734 A

### DISCLOSURE

### Technical Problem

An embodiment of the present invention is directed to providing a composition for a silicon-containing encapsulation film containing a silazane compound, and a method for manufacturing a silicon-containing encapsulation film that prevents deterioration of an organic light emitting diode by blocking moisture and oxygen using the same.

### Technical Solution

In one general aspect, a composition for a silicon-containing encapsulation film contains a silazane compound represented by the following Chemical Formula 1:

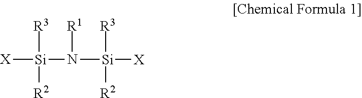

in Chemical Formula 1,
R¹ is C1-C7 alkyl, C2-C7 alkenyl, C2-C7 alkynyl, C3-C10 cycloalkyl, or C6-C12 aryl;
R² and R³ are each independently hydrogen, C1-C7 alkyl, C2-C7 alkenyl, C2-C7 alkynyl, C3-C10 cycloalkyl, C6-C12 aryl, C1-C7 haloalkyl, or halogen; and
X is halogen.

Preferably, in Chemical Formula 1, R¹ may be C1-C5 alkyl, C2-C5 alkenyl, C2-C5 alkynyl, C3-C6 cycloalkyl, or C6-C12 aryl, and R² and R³ may be each independently hydrogen, C1-C5 alkyl, C2-C5 alkenyl, C2-C5 alkynyl, C3-C6 cycloalkyl, C6-C12 aryl, C1-C5 haloalkyl, or halogen.

According to an exemplary embodiment of the present invention, the silazane compound may be represented by the following Chemical Formula 2:

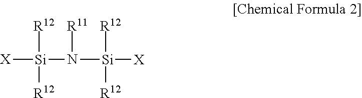

in Chemical Formula 2,
R¹¹ is C1-C7 alkyl, C2-C7 alkenyl, C2-C7 alkynyl, C3-C10 cycloalkyl, or C6-C12 aryl;
R¹² is hydrogen, C1-C7 alkyl, C2-C7 alkenyl, C2-C7 alkynyl, C3-C10 cycloalkyl, C6-C12 aryl, C1-C7 haloalkyl, or halogen; and
X is halogen.

According to an exemplary embodiment, in Chemical Formula 1, X may be Cl.

According to an exemplary embodiment, the silazane compound may be selected from the following compounds:

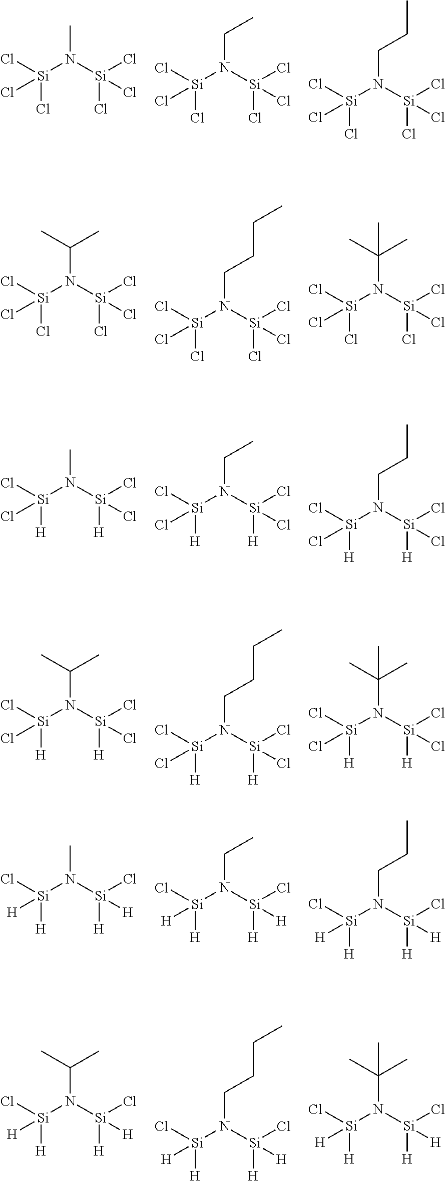

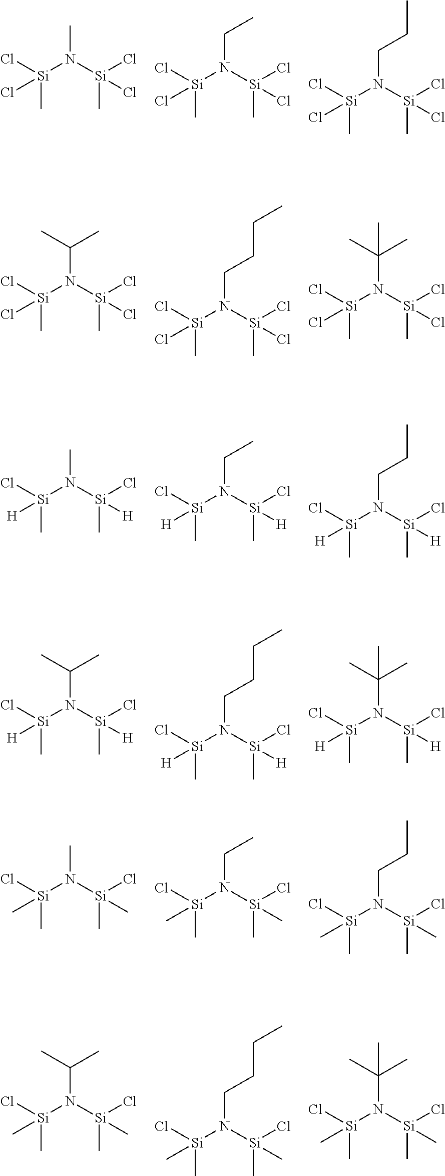

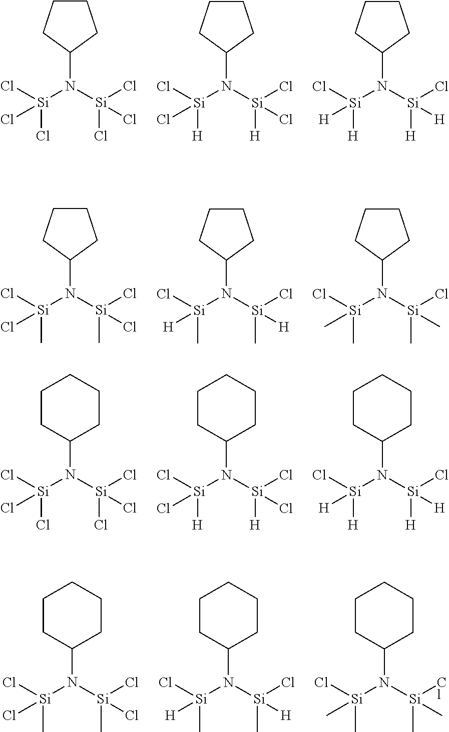

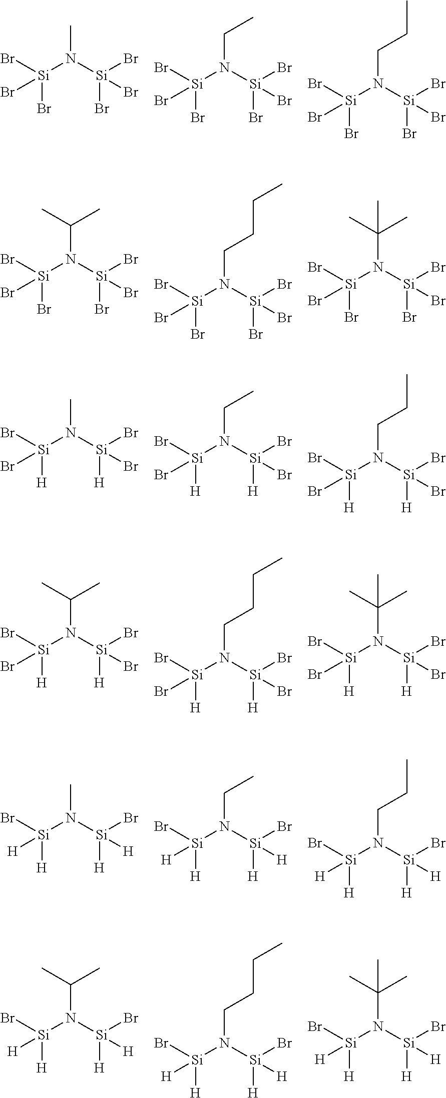

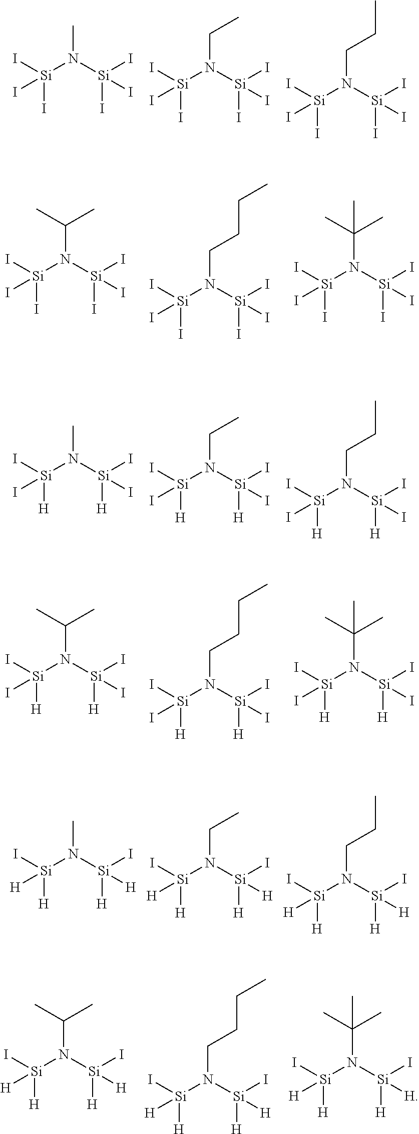

In another general aspect, a method for manufacturing a silicon-containing encapsulation film includes depositing a silicon-containing encapsulation film using a silazane compound or a composition for a silicon-containing encapsulation film containing the silazane compound, and a reaction gas, the silazane compound being represented by the following Chemical Formula 1:

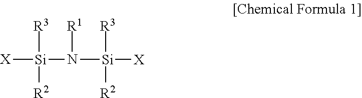

in Chemical Formula 1,
R¹ to R³ and X are as defined above.

The method for manufacturing a silicon-containing encapsulation film may further include adsorbing the silazane compound represented by Chemical Formula 1 or the composition for a silicon-containing encapsulation film containing the silazane compound onto a substrate; and injecting the reaction gas into the substrate to form a silicon-containing encapsulation film.

The method for manufacturing a silicon-containing encapsulation film may further include simultaneously injecting, into the substrate, the silazane compound represented by Chemical Formula 1 or the composition for a silicon-containing encapsulation film containing the silazane compound, and the reaction gas to form a silicon-containing encapsulation film.

In the method for manufacturing a silicon-containing encapsulation film, a temperature of the substrate may be 200° C. or lower, and the reaction gas may be one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C1 to C12 saturated or unsaturated hydrocarbon, hydrogen (H₂), argon (Ar), and helium (He).

The silicon-containing encapsulation film manufactured by the method for manufacturing a silicon-containing encapsulation film according to an exemplary embodiment of the present invention may be a silicon oxide film or a silicon nitride film, and may have a water vapor transmission rate of 0.1 g/[m²-day] or less.

### Advantageous Effects

As set forth above, when the composition for a silicon-containing encapsulation film containing the silazane compound of the present invention is used, it is possible to manufacture a high-purity encapsulation film having a significantly small content of carbon and other impurities even in a low-temperature process.

Further, in the method for manufacturing a silicon-containing encapsulation film of the present invention, the composition for a silicon-containing encapsulation film containing the silazane compound of the present invention is used, such that an encapsulation film having a high deposition rate and a low content of impurities may be manufactured.

Therefore, the silicon-containing encapsulation film manufactured according to the manufacturing method of the present invention has excellent performance in preventing deterioration of an organic light emitting diode by blocking moisture and oxygen.

### Best Mode

Hereinafter, a composition for a silicon-containing encapsulation film containing a silazane compound of the present invention and a method for manufacturing a silicon-containing encapsulation film using the same will be described in detail.

Unless the context clearly indicates otherwise, singular forms used in the present invention may be intended to include plural forms.

In addition, a numerical range used in the present invention includes upper and lower limits and all values within these limits, increments logically derived from a form and span of a defined range, all double limited values, and all possible combinations of the upper and lower limits in the numerical range defined in different forms. Unless otherwise specifically defined in the specification of the present invention, values out of the numerical range that may occur due to experimental errors or rounded values also fall within the defined numerical range.

The expression “comprise(s)” described in the present invention is intended to be an open-ended transitional phrase having an equivalent meaning to “include(s)”, “contain(s)”, “have (has)”, and “are (is) characterized by”, and does not exclude elements, materials, or steps, all of which are not further recited herein.

“Alkyl” described in the present invention means a linear or branched non-cyclic hydrocarbon, and may have 1 to 10 carbon atoms and preferably 1 to 5 carbon atoms. In addition, in another aspect, alkyl may have 1 to 3 carbon atoms.

“Alkenyl” described in the present invention means a linear or branched saturated non-cyclic hydrocarbon having at least one carbon-carbon double bond, and includes, but is not limited to, vinyl, allyl, 1-butenyl, 2-butenyl, isobutylenyl, 1-pentenyl, 2-pentenyl, 3-methyl-1-butenyl, 2-methyl-2-butenyl, 2,3-dimethyl-2-butenyl, 1-hexenyl, 2-hexenyl, 3-hexenyl, 1-heptenyl, 2-heptenyl, 3-heptenyl, 1-octenyl, 2-octenyl, 3-octenyl, 1-nonenyl, 2-nonenyl, 3-nonenyl, 1-decenyl, 2-decenyl, and 3-decenyl. These alkenyl groups may be optionally substituted. Alkenyl includes radicals having “cis” and “trans” orientations, or alternatively, “E” and “Z” orientations.

“Alkynyl” described in the present invention means a linear or branched saturated non-cyclic hydrocarbon having at least one carbon-carbon triple bond, and includes, but is not limited to, an ethynyl group, a propynyl group, a butynyl group, a butadiynyl group, a pentynyl group, a pentadiynyl group, a hexynyl group, a hexadiynyl group, and isomers thereof.

“Cycloalkyl” described in the present invention means a monocyclic or polycyclic saturated ring containing carbon and hydrogen atoms and having no carbon-carbon multiple bonds. Cycloalkyl includes, but is not limited to, cyclopropyl, cyclobutyl, cyclopentyl, cyclohexyl, and cycloheptyl. The cycloalkyl group may be optionally substituted.

“Halogen” described in the present invention means fluorine, chlorine, bromine, or iodine.

“Haloalkyl” described in the present invention means an alkyl group in which one or more hydrogen atoms are substituted with halogen atoms. For example, haloalkyl includes —CF₃, —CHF₂, —CH₂F, —CBr₃, —CHBr₂, —CH₂Br, —CCl₃, —CHCl₂, —CH₂CI, —CI₃, —CHI₂, —CH₂I, —CH₂—CF₃, —CH₂—CHF₂, —CH₂—CH₂F, —CH₂—CBr₃, —CH₂—CHBr₂, —CH₂—CH₂Br, —CH₂—CCl₃, —CH₂—CHCl₂, —CH₂—CH₂CI, —CH₂—CI₃, —CH₂—CHI₂, —CH₂—CH₂I, and the like. Here, alkyl and halogen are as defined above.

“Aryl” described in the present invention means a carbocyclic aromatic group containing 5 to 10 ring atoms. Representative examples thereof include, but are not limited to, phenyl, tolyl, xylyl, naphthyl, tetrahydronaphthyl, anthracenyl, fluorenyl, indenyl, and azulenyl. Furthermore, aryl is carbocyclic aromatic groups linked by alkylene or alkenylene or linked by one or more heteroatoms selected from B, O, N, C(═O), P, P(═O), S, S(═O)₂, and Si atoms.

The number of carbon atoms described in the present invention does not include the number of carbon atoms of a substituent, and as an example, C1-C7 alkyl means alkyl having 1 to 7 carbon atoms not including the number of carbon atoms of a substituent of alkyl.

The present invention provides a composition for a silicon-containing encapsulation film containing a silazane compound represented by the following Chemical Formula 1:

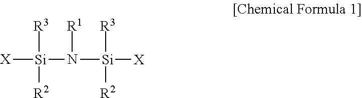

in Chemical Formula 1,
R₁ is C1-C7 alkyl, C2-C7 alkenyl, C2-C7 alkynyl, C3-C10 cycloalkyl, or C6-C12 aryl;
R² and R³ are each independently hydrogen, C1-C7 alkyl, C2-C7 alkenyl, C2-C7 alkynyl, C3-C10 cycloalkyl, C6-C12 aryl, C1-C7 haloalkyl, or halogen; and
X is halogen.

The silazane compound represented by Chemical Formula 1 has a high vapor pressure. Accordingly, when a composition for a silicon-containing encapsulation film containing the same is used, it is possible to manufacture an encapsulation film with a significantly improved deposition rate at a low temperature, and contents of carbon and other impurities are low, such that a high-quality silicon-containing encapsulation film with high purity and high durability may be obtained.

Specifically, the silazane compound represented by Chemical Formula 1 is a compound in which two silicon atoms are bonded to a central nitrogen atom, forms a compound in a stable liquid state at room temperature and atmospheric pressure, has excellent volatility with a vapor pressure of 30 torr or more at 70° C., and has a significantly high deposition rate even when deposited at a low temperature of less than 100° C., as a practical example, only at 90° C.

In addition, when a silicon-containing encapsulation film is formed using the silazane compound represented by Chemical Formula 1, excellent cohesion and excellent step coverage may be obtained. In addition, the silazane compound has the structure of Chemical Formula 1, such that it is possible to easily form a silicon-containing encapsulation film having high thermal stability, low activation energy, excellent reactivity, high purity due to no production of non-volatile by-products, and excellent stress strength.

In an exemplary embodiment, in Chemical Formula 1, R¹ may be C1-C5 alkyl, C2-C5 alkenyl, C2-C5 alkynyl, C3-C6 cycloalkyl, or C6-C12 aryl, and R² and R³ may be each independently hydrogen, C1-C5 alkyl, C2-C5 alkenyl, C2-C5 alkynyl, C3-C6 cycloalkyl, C6-C12 aryl, C1-C5 haloalkyl, or halogen.

According to an exemplary embodiment of the present invention, the silazane compound may be represented by the following Chemical Formula 2:

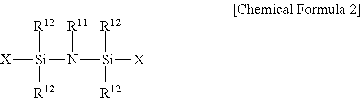

R¹¹ is C1-C7 alkyl, C2-C7 alkenyl, C2-C7 alkynyl, C3-C10 cycloalkyl, or C6-C12 aryl;
R¹² is hydrogen, C1-C7 alkyl, C2-C7 alkenyl, C2-C7 alkynyl, C3-C10 cycloalkyl, C6-C12 aryl, C1-C7 haloalkyl, or halogen; and
X is halogen.

According to an exemplary embodiment of the present invention, in Chemical Formula 1, X may be Cl.

According to an exemplary embodiment of the present invention, the silazane compound may be selected from the following compounds:

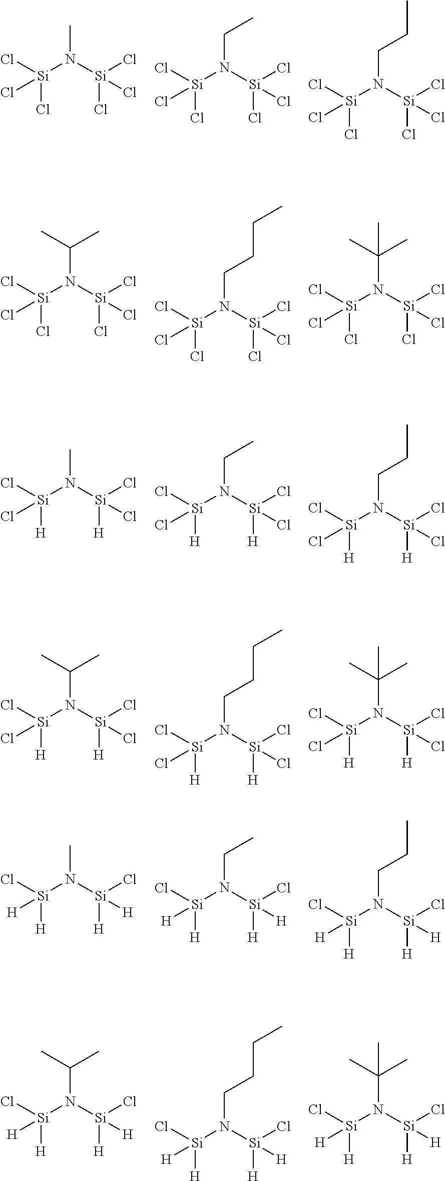

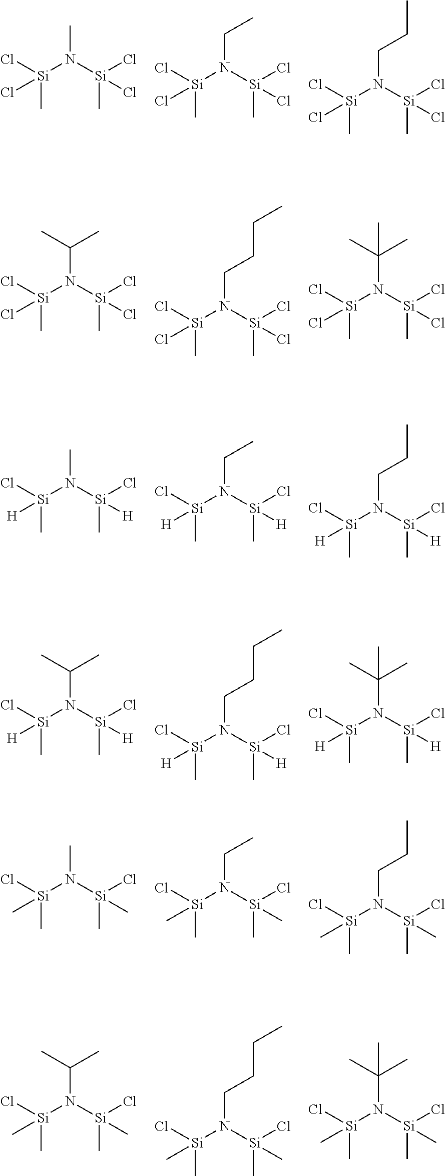

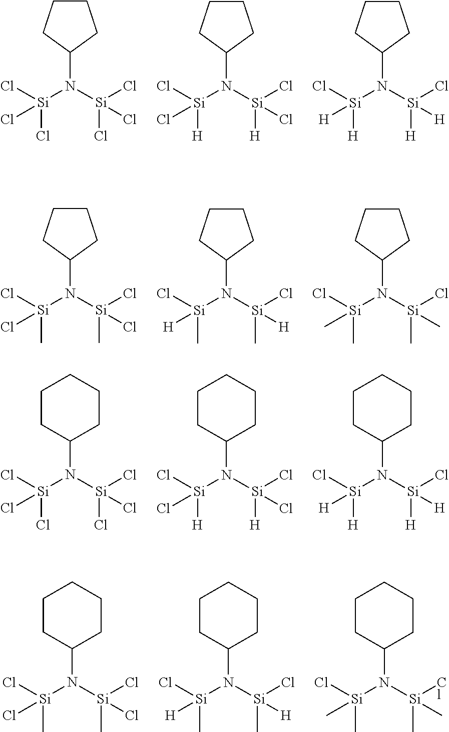

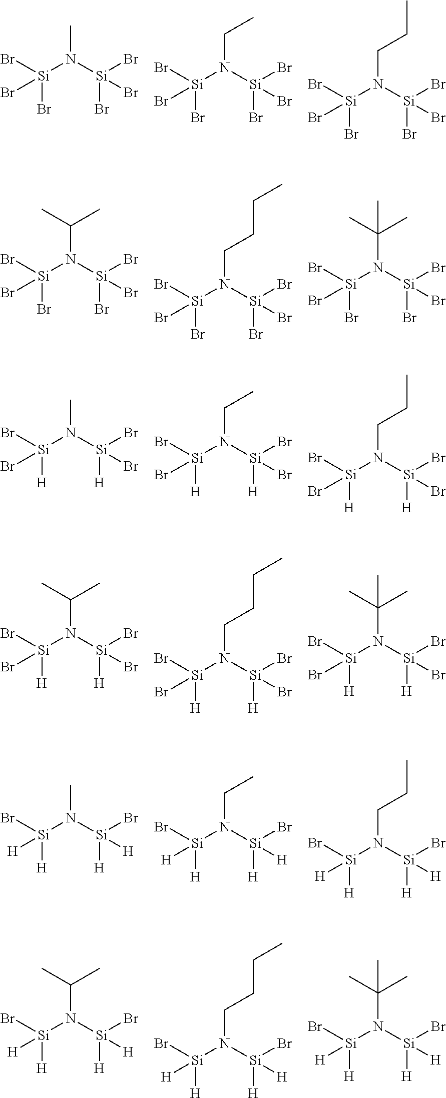

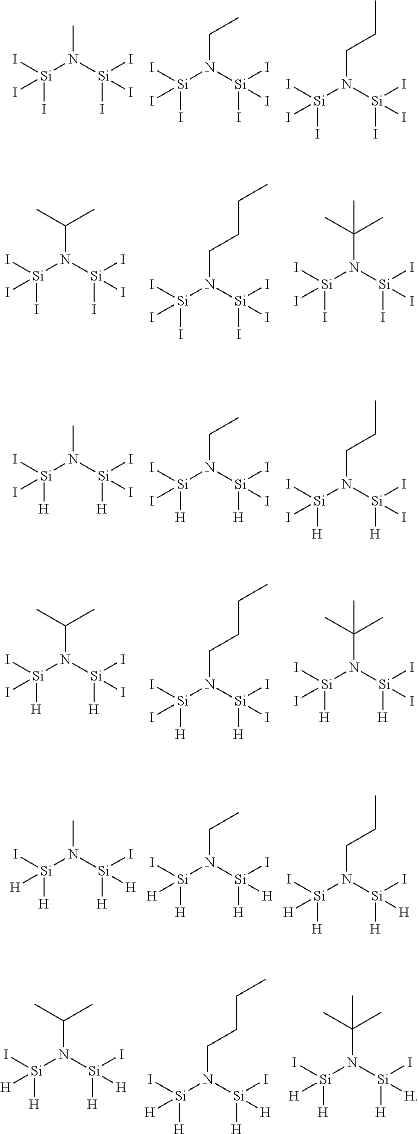

According to an exemplary embodiment of the present invention, a silazane compound represented by the following Chemical Formula 1 may be produced by any method available in the field of organic synthesis. For example, a compound represented by the following Chemical Formula 1 may be produced by reacting a compound represented by the following Chemical Formula 11 with a compound represented by the following Chemical Formula 12:

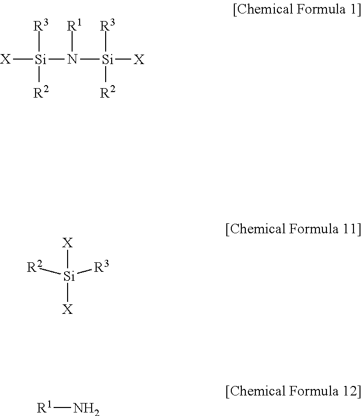

in Chemical Formulas 1, 11, and 12,
R¹ is C1-C7 alkyl, C2-C7 alkenyl, C2-C7 alkynyl, C3-C10 cycloalkyl, or C6-C12 aryl;
R² and R³ are each independently hydrogen, C1-C7 alkyl, C2-C7 alkenyl, C2-C7 alkynyl, C3-C10 cycloalkyl, C6-C12 aryl, C1-C7 haloalkyl, or halogen; and
X is halogen.

According to an exemplary embodiment of the present invention, the method for synthesizing the silazane compound may be performed at −70 to 10° C. for 1 to 10 hours and preferably at −50 to 0° C. for 2 to 6 hours.

The present invention provides a method for manufacturing a silicon-containing encapsulation film, the method including depositing a silicon-containing encapsulation film using a silazane compound or a composition for a silicon-containing encapsulation film containing the silazane compound, and a reaction gas, the silazane compound being represented by the following Chemical Formula 1:

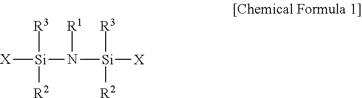

in Chemical Formula 1,
R¹ to R³ and X are the same as defined above.

Specifically, the method for manufacturing a silicon-containing encapsulation film according to an exemplary embodiment of the present invention may further include: adsorbing the silazane compound represented by Chemical Formula 1 or the composition for a silicon-containing encapsulation film containing the silazane compound onto a substrate; and injecting the reaction gas into the substrate onto which the silazane compound or the composition for a silicon-containing encapsulation film is adsorbed to form a silicon-containing encapsulation film. In this case, specifically, the method for manufacturing a silicon-containing encapsulation film may further include: adsorbing the silazane compound represented by Chemical Formula 1 or the composition for a silicon-containing encapsulation film containing the silazane compound onto a substrate; purging the remaining silazane compound or a composition containing the remaining silazane compound and by-products; injecting a reaction gas into the substrate to form a silicon-containing encapsulation film; and purging residual reaction gas and by-products.

In addition, the silicon-containing encapsulation film according to an exemplary embodiment may be manufactured by simultaneously injecting, into the substrate, the silazane compound represented by Chemical Formula 1 or the composition for a silicon-containing encapsulation film containing the silazane compound, and the reaction gas.

In the method for manufacturing a silicon-containing encapsulation film according to the present invention, the silazane compound represented by Chemical Formula 1, which is liquid at room temperature and has high volatility and excellent thermal stability, is used, such that it is possible to manufacture a silicon-containing encapsulation film that is easy to handle and has excellent purity may be manufactured at a high deposition rate even at a low temperature and/or low power. Furthermore, the silicon-containing encapsulation film manufactured by the manufacturing method of the present invention may have excellent durability and electrical properties and may prevent permeation of moisture and oxygen.

In the method for manufacturing a silicon-containing encapsulation film according to an exemplary embodiment of the present invention, the silicon-containing encapsulation film may be deposited by any method within a range recognized by those skilled in the art, preferably may be formed by atomic layer deposition (ALD), chemical vapor deposition (CVD), metal organic chemical vapor deposition (MOCVD), low pressure vapor deposition (LPCVD), plasma-enhanced vapor deposition (PECVD), or plasma-enhanced atomic layer deposition (PEALD), and more specifically, may be formed by plasma-enhanced vapor deposition (PECVD) in terms of easy deposition of an encapsulation film and excellent properties of the manufactured encapsulation film, but the present invention is not limited thereto.

In addition, in the method for manufacturing a silicon-containing encapsulation film according to an exemplary embodiment of the present invention, a temperature of the substrate may be 200° C. or lower, specifically, the deposition may be performed at 50 to 200° C., the temperature of the substrate to be deposited located inside the chamber may be lower than 120° C. and typically 100° C. or lower due to extremely excellent properties of a silicon precursor for deposition of the silazane compound according to Chemical Formula 1 of the present invention, such as excellent low-temperature volatility and high reactivity, and deposition of a silicon-containing encapsulation film, which includes supplying the silazane compound according to an exemplary embodiment to the chamber in which the substrate to be deposited is located, may be performed at a temperature of lower than 100° C., and more specifically, at a low temperature of 95° C. or lower.

In an exemplary embodiment of the present invention, the reaction gas used in the method for manufacturing a silicon-containing encapsulation film may be one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C1 to C12 saturated or unsaturated hydrocarbon, hydrogen (H₂), argon (Ar), and helium (He), specifically, may be one or two or more selected from oxygen (O₂), nitrogen monoxide (NO), nitrous oxide (N₂O), nitrogen dioxide (NO₂), ammonia (NH₃), and nitrogen (N₂), and more specifically, may be one or two or more selected from nitrous oxide (N₂O), nitrogen dioxide (NO₂), ammonia (NH₃), hydrogen (H₂), and nitrogen (N₂), but is not limited thereto.

In the method for manufacturing a silicon-containing encapsulation film according to an exemplary embodiment of the present invention, the silazane compound and the reaction gas may be supplied organizationally or independently of each other. In addition, the silazane compound and the reaction gas may be supplied continuously or discontinuously, respectively, and the discontinuous supply may include a pulse form.

In the method for manufacturing a silicon-containing encapsulation film according to an exemplary embodiment, deposition conditions may be adjusted according to the structure or thermal characteristics of the desired encapsulation film, and examples of the deposition conditions include an input flow rate of the composition for a silicon-containing encapsulation film containing the silazane compound, an input flow rate of the reaction gas, an input flow rate of a carrier gas, a pressure, and a temperature of the substrate to be deposited. As a non-limiting example of these deposition conditions, the input flow rate of the composition for a silicon-containing encapsulation film containing the silazane compound may be 10 to 1,000 cc/min, the input flow rate of the reaction gas may be 1 to 10,000 cc/min, the input flow rate of the carrier gas may be 10 to 10,000 cc/min, the pressure may be 0.5 to 10 torr, and the temperature of the substrate to be deposited may be 200° C. or lower, specifically, 50 to 200° C., more specifically, 50 to 120° C., and typically 60 to 100° C., but the deposition conditions are not limited thereto. In addition, in the case of using plasma-enhanced atomic layer deposition (PEALD), in which the reaction gas is in a plasma-activated state, RF power may be to 50 to 1,000 W, but is not limited thereto.

The silicon-containing encapsulation film manufactured by the method for manufacturing a silicon-containing encapsulation film according to an exemplary embodiment of the present invention may be a silicon oxide film or a silicon nitride film, and in addition, various high-quality encapsulation films containing silicon may be manufactured within a range recognized by those skilled in the art.

The silicon-containing encapsulation film manufactured by the method for manufacturing a silicon-containing encapsulation film of the present invention may be used to protect an organic light emitting diode from moisture and oxygen.

The silicon-containing encapsulation film manufactured by the method for manufacturing a silicon-containing encapsulation film of the present invention may have a water vapor transmission rate of 0.1 g/[m²-day] or less, preferably 0.05 g/[m²-day] or less, and more preferably 0.015 g/[m²-day] or less. Accordingly, the silicon-containing encapsulation film manufactured by the manufacturing method of the present invention has significantly improved moisture and oxygen blocking performance, and thus may prevent a decrease in lifespan of an organic light emitting diode employing the silicon-containing encapsulation film.

In the measurement of the water vapor transmission rate of the silicon-containing encapsulation film, a water vapor transmission rate analyzer (WVTR, MOCON, Aquatran 2) is used, nitrogen is used, and an area for measuring the water vapor transmission rate is set to 50 cm².

The structure of the encapsulation film manufactured by the method for manufacturing a silicon-containing encapsulation film according to an exemplary embodiment of the present invention may cover a surface and/or side surface of an organic light emitting diode according to the demand thereof. A thickness of the encapsulation film may be 5 to 2,000 nm, preferably 200 to 1,000 nm, and more preferably 500 to 800 nm.

Hereinafter, the composition for a silicon-containing encapsulation film containing a silazane compound according to the present invention and the method for manufacturing a silicon-containing encapsulation film using the same will be described in more detail with reference to specific Examples.

However, the following Examples are only reference examples for describing the present invention in detail, and the present invention is not limited thereto and may be implemented in various forms. In addition, the terms used in the present invention are only to effectively describe specific Examples, but are not intended to limit the present invention.

### Production Example 1

After vacuum drying was performed in a 5 L high-pressure reactor including a stirrer and a condenser, 2 L of n-pentane was added, and 40 g (1.29 mol) of methylamine was added while maintaining the internal temperature at −40° C. The mixture was stirred for 30 minutes, and then 86.8 g (0.86 mol) of dichlorosilane was slowly added while maintaining the temperature. After completion of the addition, the mixture was stirred for 4 hours while maintaining the internal temperature at −10° C. A salt and a solvent were removed by vacuum filtration and vacuum distillation to obtain 38 g of MeN(SiH₂C1)₂ (yield: 55%).

¹H NMR (400 MHz, C6D6) δ 2.7(s, 3H), 5.07 (s, 4H)

### [Example 1] Silicon Oxide Film for Encapsulation Film

An encapsulation film was evaluated using the silazane compound produced in Production Example 1 in a general plasma-enhanced atomic layer deposition apparatus using a known plasma-enhanced atomic layer deposition.

Nitrous oxide was used as a reaction gas together with plasma, and argon, an inert gas, was used as a carrier gas. A silicon wafer on which a silicon oxide film was to be formed was transferred into a deposition chamber and maintained at 90° C. The silazane compound of Production Example 1 in a bubbler-type stainless steel container was vaporized at a vapor pressure of Torr, the vaporized silazane compound was transferred onto a substrate using 50 sccm of argon gas as a carrier gas for adsorption onto the substrate, and then unreacted compounds were removed using 500 sccm of argon gas. A silicon oxide film was formed using 800 sccm of nitrous oxide gas as a reaction gas and 800 W of plasma, and then unreacted compounds were removed using 500 sccm of argon gas.

A silicon oxide film was formed by repeating the above processes as one cycle. A thickness of the formed silicon oxide film was measured using an ellipsometer, and it was confirmed that a deposition thickness of the silicon oxide film per unit cycle was 2.01 Å and a refractive index was 1.47 at 633 nm. In addition, as a result of composition analysis using X-ray photoelectron spectroscopy, it was confirmed that ratios of silicon and oxygen were 33.5% and 66.5%, respectively.

To evaluate a water vapor transmission rate, the thin film was deposited at 700 Å on a polyethylene naphthalate (PEN) film, and then a water vapor transmission rate was analyzed. As a result, an excellent result of 1.5×10⁻³ g/[m²-day]was confirmed.

### [Example 2] Silicon Nitride Film for Encapsulation Film

An encapsulation film was evaluated using the silazane compound produced in Production Example 1 in a general plasma-enhanced atomic layer deposition apparatus using a known plasma-enhanced atomic layer deposition.

Ammonia was used as a reaction gas together with plasma, and nitrogen, an inert gas, was used as a carrier gas. A silicon wafer on which a silicon nitride film was to be formed was transferred into a deposition chamber and maintained at 90° C. The silazane compound of Production Example 1 in a bubbler-type stainless steel container was vaporized at a vapor pressure of Torr, the vaporized silazane compound was transferred onto a substrate using 50 sccm of nitrogen gas as a carrier gas for adsorption onto the substrate, and then unreacted compounds were removed using 500 sccm of nitrogen gas. A silicon nitride film was formed using 1,000 sccm of ammonia gas as a reaction gas and 800 W of plasma, and then unreacted compounds were removed using 500 sccm of nitrogen gas. Next, the silicon nitride film was subjected to a surface treatment using 1,000 sccm of nitrogen gas and 800 W of plasma, and then unreacted compounds were removed using 500 sccm of nitrogen gas.

A silicon nitride film was formed by repeating the above processes as one cycle. A thickness of the formed silicon nitride film was measured using an ellipsometer, and it was confirmed that a deposition thickness of the silicon nitride film per unit cycle was 0.82 Å and a refractive index was 1.97 at 633 nm. In addition, as a result of composition analysis using X-ray photoelectron spectroscopy, it was confirmed that the ratios of silicon and nitrogen were 43.1% and 56.8%, respectively.

To evaluate a water vapor transmission rate, the thin film was deposited at 700 Å on a polyethylene naphthalate (PEN) film, and then a water vapor transmission rate was analyzed. As a result, an excellent result of 1×10⁻⁴ g/[m²-day]was confirmed.

### [Example 3] Silicon Nitride Film for Encapsulation Film

An encapsulation film was evaluated using the silazane compound produced in Production Example 1 in a general plasma-enhanced chemical vapor deposition apparatus using a known plasma-enhanced chemical vapor deposition.

A silicon wafer on which a silicon nitride film was to be formed was transferred into a deposition chamber and maintained at 90° C. The silazane compound of Production Example 1 in a bubbler-type stainless steel container was vaporized at a vapor pressure of 0.1 Torr, and the vaporized silazane compound was transferred into the chamber using 5 sccm of nitrogen gas as a carrier gas. At the same time, nitrogen, hydrogen, and ammonia were used as reaction gases, and a silicon nitride film was formed using 800 W of plasma. Detailed process conditions and results are as shown in Table 1. As a result of composition analysis using X-ray photoelectron spectroscopy, it was confirmed that the ratios of silicon and nitrogen were about 43% and 57%, respectively.

### EXAMPLES 4 TO 7

Silicon nitride films were deposited in the same manner as that of Example 3 except that only the gas ratio was changed. The process conditions and results are shown in Table 1.

TABLE 1
Silicon nitride film deposition conditions and results using plasma-enhanced chemical vapor deposition

| | Nitrogen | | | | | | | | | |
|---|---|---|---|---|---|---|---|---|---|---|
| | for | | | | | Ellipsometer analysis results | | | | Water vapor |
| | precursor | Gas ratio | | | Deposition | | Refractive | Deposition | | transmission |
| | transfer | Nitrogen | Hydrogen | Ammonia | time | Thickness | index | rate | Permeability | rate |
| Example | sccm | % | % | % | min | Å | — | Å/min | % | g/(m² · day) |
| 3 | 5 | 30 | 58 | 12 | 3 | 495 | 1.86 | 165 | 99.8 | 9.73E−03 |
| | | | | | 5 | 815 | 1.86 | 163 | 99.3 | 6.24E−03 |
| | | | | | 7 | 1,180 | 1.86 | 169 | 98.8 | 5.00E−05 |
| 4 | 5 | 60 | 28 | 12 | 5 | 804 | 1.8 | 160 | 99.1 | 6.47E−03 |
| 5 | 5 | 60 | 37 | 3 | 5 | 796 | 1.85 | 198 | 98.6 | 5.65E−03 |
| 6 | 5 | 30 | 67 | 3 | 5 | 830 | 1.86 | 196 | 98.8 | 4.62E−03 |
| 7 | 5 | 30 | 69 | 1 | 4 | 880 | 1.88 | 220 | 98.3 | 1.26E−02 |

Referring to the above results, the composition for a silicon-containing encapsulation film containing the silazane compound of Production Example 1 of the present invention has a high vapor pressure and may exhibit an excellent deposition rate, and a high-quality silicon-containing encapsulation film having high purity and high durability may be manufactured because the content of carbon and other impurities is low. The composition for a silicon-containing encapsulation film containing the silazane compound, which is a specific compound, according to an exemplary embodiment of the present invention exhibits excellent volatility and high reactivity, such that it is possible to manufacture an encapsulation film that may be deposited at a low temperature and has a more uniform and improved quality.

It may be appreciated that the silicon-containing encapsulation film manufactured by the manufacturing method of the present invention has significantly excellent moisture and oxygen blocking performance due to an improved water vapor transmission rate, and when the silicon-containing encapsulation film is used in an organic light emitting diode, it is expected to be used as an excellent material that may prevent moisture and oxygen from permeating and reducing lifespan.

Hereinabove, although the present invention has been described by specific matters and limited Examples and Comparative Examples, they have been provided only for assisting in the entire understanding of the present invention. Therefore, the present invention is not limited to the Examples. Various modifications and changes may be made by those skilled in the art to which the present invention pertains from this description.

Therefore, the spirit of the present invention should not be limited to the described Examples, but the claims and all modifications equal or equivalent to the claims are intended to fall within the spirit of the present invention.

1. A composition for a silicon-containing encapsulation film, the composition comprising a silazane compound represented by the following Chemical Formula 1: 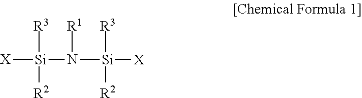
in Chemical Formula 1,
R¹ is C1-C7 alkyl, C2-C7 alkenyl, C2-C7 alkynyl, C3-C10 cycloalkyl, or C6-C12 aryl;
R² and R³ are each independently hydrogen, C1-C7 alkyl, C2-C7 alkenyl, C2-C7 alkynyl, C3-C10 cycloalkyl, C6-C12 aryl, C1-C7 haloalkyl, or halogen; and
X is halogen.

2. The composition of claim 1, wherein in Chemical Formula 1,
R¹ is C1-C5 alkyl, C2-C5 alkenyl, C2-C5 alkynyl, C3-C6 cycloalkyl, or C6-C12 aryl;
R² and R³ are each independently hydrogen, C1-C5 alkyl, C2-C5 alkenyl, C2-C5 alkynyl, C3-C6 cycloalkyl, C6-C12 aryl, C1-C5 haloalkyl, or halogen; and
X is halogen.

3. The composition of claim 1, wherein the silazane compound is represented by the following Chemical Formula 2: 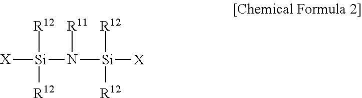
in Chemical Formula 2,
R¹¹ is C1-C7 alkyl, C2-C7 alkenyl, C2-C7 alkynyl, C3-C10 cycloalkyl, or C6-C12 aryl;
R¹² is hydrogen, C1-C7 alkyl, C2-C7 alkenyl, C2-C7 alkynyl, C3-C10 cycloalkyl, C6-C12 aryl, C1-C7 haloalkyl, or halogen; and
X is halogen.

4. The composition of claim 1, wherein in Chemical Formula 1, X is Cl.

5. The composition of claim 1, wherein the silazane compound is selected from the following compounds:

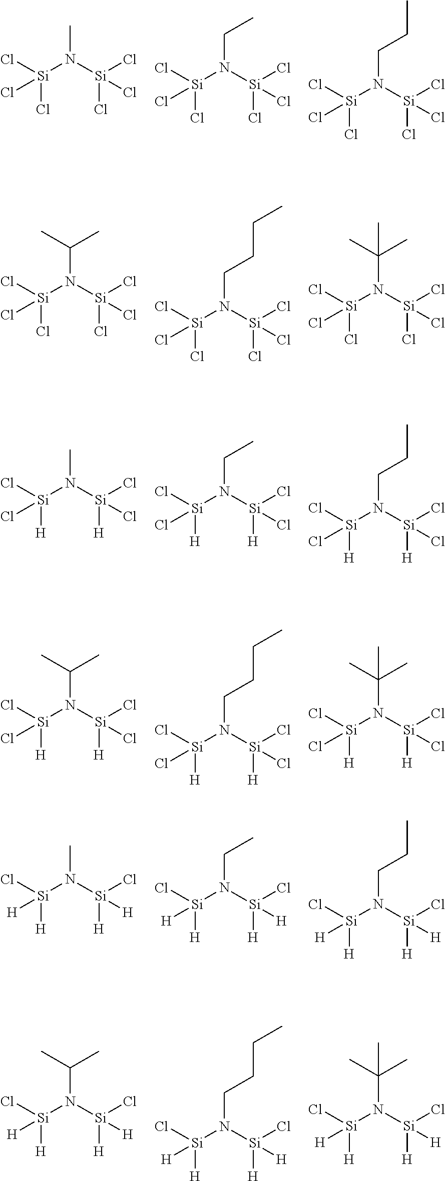

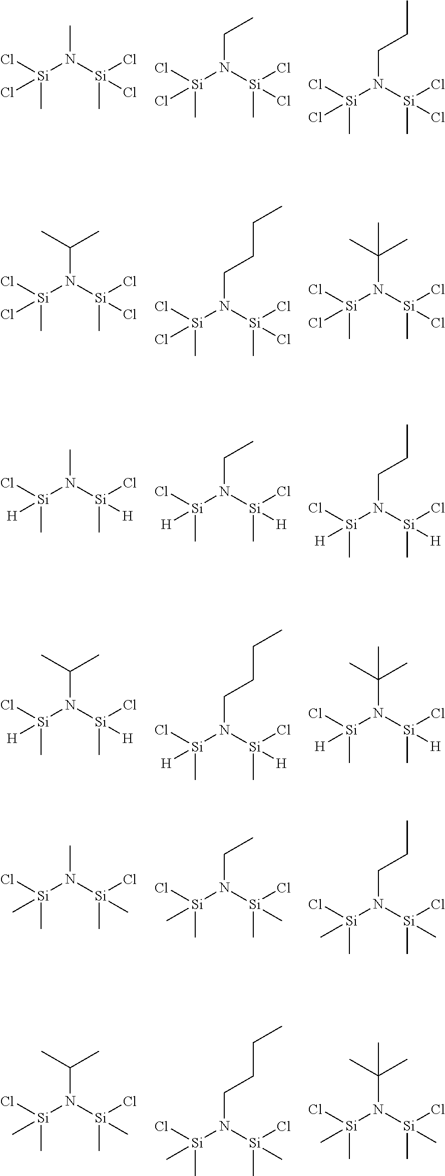

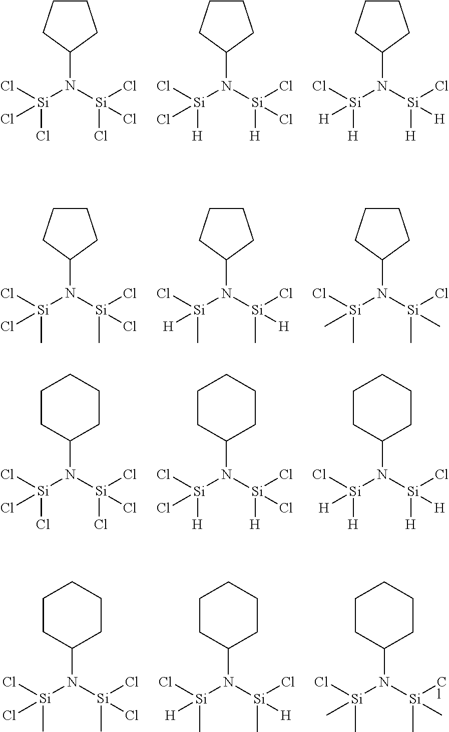

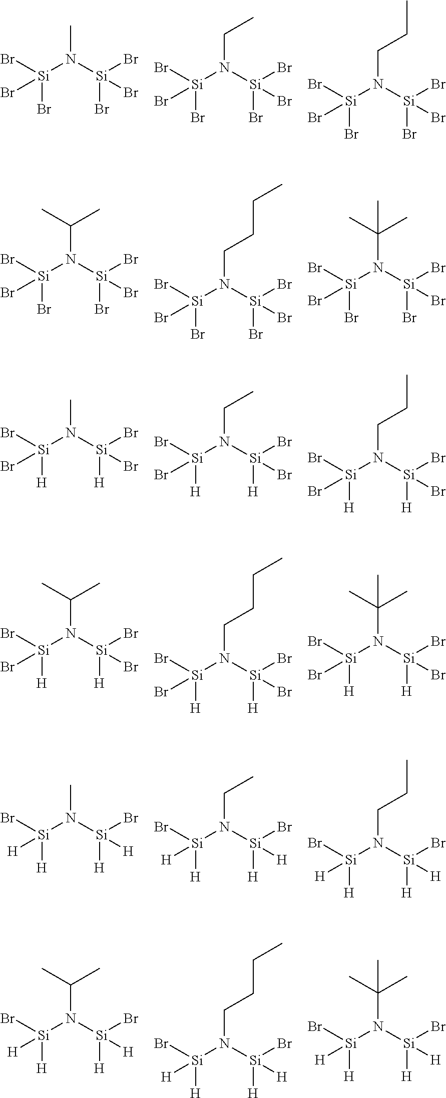

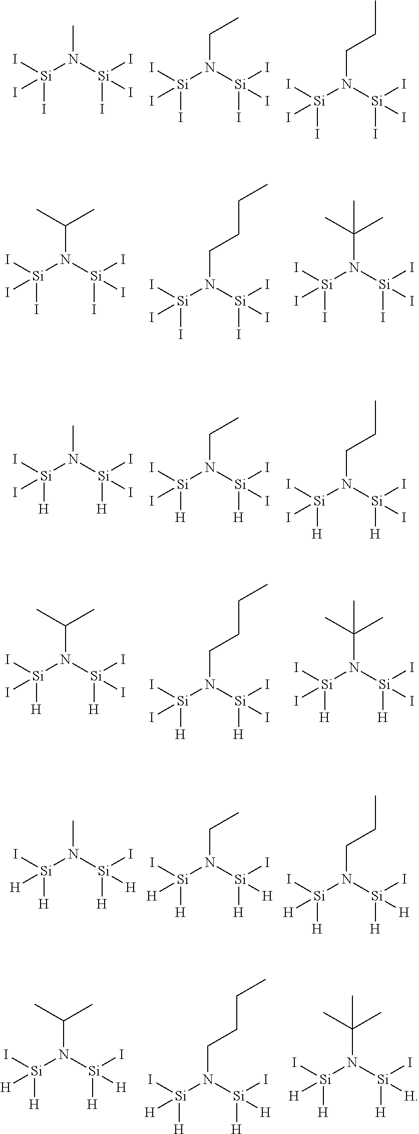

6. A method for manufacturing a silicon-containing encapsulation film, the method comprising: depositing a silicon-containing encapsulation film using a silazane compound or a composition for a silicon-containing encapsulation film containing the silazane compound, and a reaction gas, the silazane compound being represented by the following Chemical Formula 1: 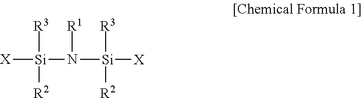
in Chemical Formula 1,
R₁ to R₃ and X are the same as defined in claim 1.

7. The method of claim 6, further comprising:
adsorbing a precursor containing the silazane compound represented by Chemical Formula 1 or the composition for a silicon-containing encapsulation film onto a substrate; and
injecting the reaction gas into the substrate onto which the silazane compound or the composition for a silicon-containing encapsulation film is adsorbed to form a silicon-containing encapsulation film.

8. The method of claim 6, further comprising simultaneously injecting, into the substrate, the silazane compound represented by Chemical Formula 1 or the composition for a silicon-containing encapsulation film containing the silazane compound, and the reaction gas to form a silicon-containing encapsulation film.

9. The method of claim 6, wherein the reaction gas is one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C1 to C12 saturated or unsaturated hydrocarbon, hydrogen (H₂), argon (Ar), and helium (He).

10. The method of claim 7, wherein a temperature of the substrate is 200° C. or lower.

11. The method of claim 6, wherein the silicon-containing encapsulation film is a silicon oxide film or a silicon nitride film.

12. The method of claim 6, wherein the silicon-containing encapsulation film has a water vapor transmission rate of 0.1 g/[m²-day] or less.
